(19) United States
(12) Patent Application Publication
(10) Pub. No.: US 2007/0025167 A1
(43) Pub. Date: Feb. 1, 2007

(54) Method for testing a memory device, test unit for testing a memory device and memory device

(76) Inventors: Marco Ziegelmayer, Loschwitz (DE); Detlev Richter, Muenchen (DE); Andreas Kux, Haar (DE); Mirko Reissmann, Ottendorf-Okrilla (DE)

Correspondence Address: SLATER & MATSIL LLP, 17950 PRESTON ROAD, SUITE 1000, DALLAS, TX, 75252, US

(21) Appl. No.: 11/191,146

(22) Filed: Jul. 27, 2005

(51) Int. Cl. G11C 29/00

(52) U.S. Cl. 365/201

(57) ABSTRACT

A method, a memory device and a test unit to test such memory device is provided. The memory device comprises a memory cell array including a multitude of memory cells each having a variable characteristic. The method comprises identifying the characteristic of each memory cell and assigning memory cells of the multitude of memory cells to a weak group in dependence on the identified characteristic. Then the stored information of the memory cells assigned to the weak group is restored in order to modify the characteristics of these memory cells.

### TECHNICAL FIELD

The present invention relates to a method for testing a memory device comprising a multitude of memory cells. The invention further relates to a memory device comprising a multitude of memory cells and a testing unit in order to test such memory device.

### BACKGROUND

An EEPROM or electrically erasable programmable read only memory is a non-volatile storage unit used, e.g., in computers or other devices. An EEPROM can be programmed and erased electrically multiple times. Each bit is set by quantum tunneling electrons across a thin dielectric barrier. Each memory cell of the EEPROM can be erased and reprogrammed only a certain number of times. EEPROM memory cells may comprise different kinds of memory cells, for example a floating gate cell or a so-called nitride programmable read only memory (NROM) cell. The NROM cell is described in U.S. Pat. No. 6,011,725, which is incorporated herein by reference. Depending on the form of the memory cell one or more bits can be stored into the memory cell.

The NROM cell has two doping areas and a channel which is located between the doping areas. A gate electrode across a channel region is insulated by a dielectric layer arranged between the channel region and the gate electrode. The dielectric layer includes an oxide-nitride-oxide layer comprising a nitride layer serving as a charge-trapping layer sandwiched between the insulating oxide layers which avoid vertical retention. Charges are stored in physically different regions of the nitride layer. A first bit region is located near the first doping area and a second bit region is located near the second doping area.

The bits are programmed by means of channel hot electron programming. Electrons may be injected from the channel into the charge-trapping regions according to the applied programming voltages. Programming a first bit, so that the first bit represents a first binary value, may be performed by applying first programming voltages to the memory cell. Likewise, programming a second bit so that the second bit represents the first binary value, may be performed by applying second programming voltages to the memory cell. Programming is performed by applying several pulses of the programming voltages. For erasing a bit so that the bit represents a second binary value, hot holes or Fowler-Nordheim tunnelling can be used. Erasing of the first or second bit may be performed by applying first or second erasing voltages, respectively, to the memory cell. Performing erasing includes applying several pulses of the erasing voltages.

A bit information stored in the NROM cell is read by applying reading voltages to this cell. First reading voltages are applied to the memory cell in order to read the first bit. Second reading voltages are applied in order to read the second bit. A current flows or does not flow depending on whether there are charges trapped in the respective bit region. Reduced or no current flows when charges trapped in the respective bit region representing the first binary value. A normal current representing the second binary value flows, while there are no or nearly no charges trapped in the respective bit region.

During applying a reading voltage to the memory cell the resulting amount of current flow depends on the threshold voltage of the memory cell. If the applied reading voltage is larger than the threshold voltage the normal current flows. If the applied reading voltage is less than the threshold voltage no or nearly no current flows. The threshold voltage depends on the amount of charges trapped inside the respective bit region.

Varying the threshold is used in order to represent and store the first or second binary value. The stored bit information is indicated in response to a fixed reading voltage. The threshold voltage is varied from a range below the reading voltage to a range above the reading voltage. The range above the reading voltage is called programming level. The range below the reading voltage is called erasing level. The threshold voltage is larger than the given reading voltage in order to represent the first binary value resulting in normal current flow. The threshold voltage is less than the given reading voltage in order to represent the second binary value indicated by the normal current flow.

The above mentioned concept of programming and erasing by means of varying the threshold voltage, is not limited to NROM cells, but also known by a wide variety of transistor based storage cells.

The memory device is generally tested for functionality by the manufacturer before delivery. Defective memory cells that cannot be programmed may be replaced by redundant memory cells. Alternatively, defect blocks containing one or more defect memory cells may be replaced by redundant blocks.

The durability of the memory cells, which are included in a memory cell array, may depend on the number of programming and erasing cycles already performed to the memory cells. All error-free memory cells of the memory cell array may be programmed as well as be erased nearly the same number of times until they fail. Nevertheless, the memory cell array may further comprise memory cells which are not defective but weak. That means these weak memory cells may fail much earlier than error-free memory cells. The weak memory cells are not detectable during the testing phase in order to find defect memory cells because the weak memory cells can be programmed or erased during this testing phase.

The weak memory cells may be detected by performing a so-called precycling routine, which comprises several programming and erasing cycles that the weak memory cells fail by exceeding the limited number of programming and erasing cycles of their life cycle.

After having failed, the former weak memory cells can be detected by a conventional test routine in order to detect defective cells. The detected defective memory cells can be repaired by replacing the defective memory cells by redundant memory cells.

The threshold voltage of the failed memory cells does not reach the programming level after the step of programming has been performed and/or does not reach the erasing level after erasing has been performed.

Precycling requires further testing time. Additionally, the quality of all memory cells of the device becomes lower with each programming and erasing cycle, because the remaining life cycle of the error-free memory cells is reduced.

### SUMMARY OF THE INVENTION

In preferred embodiments, test method is provided in order to detect weak memory cells which may fail much earlier than error-free memory cells. The test method for detection of the weak memory cells is based on a variable characteristic of each memory cell comprised by a memory cell array. The characteristic, which may be a threshold voltage of the memory cell, enables to indicate an information stored in the memory cell.

Memory cells are assigned to a weak group, depending upon the identified characteristics. The weak group includes error-free memory cells and weak memory cells. Clear error-free memory cells are not assigned to the weak group. During the step of assigning, clear error-free memory cells are distinguished from possible weak memory cells.

Further steps of the method only concern the memory cells assigned to the weak group. Thus, wearing of the error-free memory cells by performing unneeded programming and erasing cycles is avoided.

The stored information of the memory cells assigned to the weak group is restored in order to modify their characteristics. Restoring is performed for the purpose of artificially wearing the weak memory cells, that will fail during the next step. Actual error-free memory cells that are assigned to the weak group, will not fail during further proceedings.

Then the memory cells assigned to the weak group are programmed or erased in order to alter their stored information. If the stored information can be altered, the memory cell is error-free. If the stored information cannot be altered, the former weak memory cell has failed. The memory cell is defective and can be detected by means of detecting defective memory cells and may be repaired.

Advantageously, assigning memory cells to the weak group is performed, if the same information is stored in each memory cell in order to simplify the method and to test all memory cells at the same time.

Storing information into the memory cells is performed by programming or erasing. A programming signal applied to the memory cells to be programmed comprises a sequence of programming pulses. Restoring of programmed memory cells comprises applying at least one further programming pulse. An erasing signal comprises a sequence of pulses also. Likewise, restoring of erased memory cells comprises applying at least one further erasing pulse. Thus, means for restoring can be formed by simple amending means for storing.

Embodiments for performing the above-mentioned test method comprise means for identifying the characteristics of the memory cells, means for assigning the memory cells to the weak group and means for restoring the information stored in the memory cells assigned to the weak group. These means are arranged within the memory device. Alternatively, some of these means may be arranged within a test unit, which is connectable to the memory device.

### BRIEF DESCRIPTION OF THE DRAWINGS

For a more complete understanding of the present invention and its advantages, reference is now made to the following description taken in conjunction with the accompanying drawings, in which:

FIG. 1 shows a memory cell array comprising a multitude of memory cells;

FIG. 2 shows a histogram of threshold voltages of the memory cells of the memory cell array;

FIG. 3 shows the modified histogram of the threshold voltages of the memory cells of the memory cell array, after restoring of overerased memory cells;

FIG. 4 shows the modified histogram of the threshold voltages of the memory cells of the memory cell array, after restoring of overprogrammed memory cells;

FIG. 5 shows a block diagram of an embodiment of a memory device; and

FIG. 6 shows a block diagram of a further embodiment of the memory device coupled to a test unit.

The following list of reference symbols can be used in conjunction with the figures:
1 Memory cell array
2 Test unit
11 Memory interface
13,23 Identifying unit
14,24 Assigning unit
15 Access unit
17 Memory device
22 Test unit interface
30 Erasing range
31 Programming range
50,51 Distribution curves
100,101 Memory cells
200 Overerased memory cells
220 Modified overerased memory cells
300 Undererased memory cells
400 Underprogrammed memory cells
500 Overprogrammed memory cells
550 Modified overprogrammed memory cells
V0 Mean erasing voltage
V1 Mean programming voltage
TH1, TH2 Threshold value
VR Reading voltage

### DETAILED DESCRIPTION OF ILLUSTRATIVE EMBODIMENTS

Preferred embodiments are discussed in detail below. However, it should be noted that the present invention provides many applicable concepts that can be embodied in a wide variety of specific contexts. The specific embodiments discussed are merely illustrative of specific ways to make and use the invention and do not limit the scope of the invention.

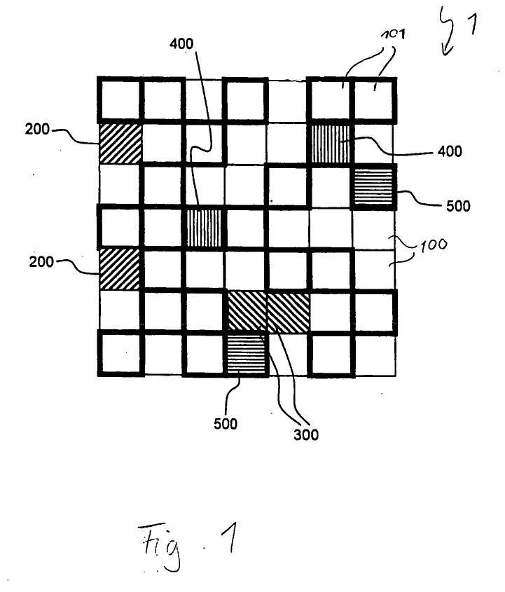

FIG. 1 shows a memory cell array 1, including a multitude of memory cells 100, 101. Each memory cell 100, 101 is operable to store information. In case of NROM memory cells this information comprises two bits. Further embodiments of memory cells may store one bit or more than two bits.

Each memory cell 100, 101 has a variable characteristic that indicates the stored information. This characteristic comprises a threshold voltage, indicating whether the stored bit represents a first binary value or a second binary value. The stored bit is indicated in response to a reading voltage applied to the memory cell. This means that a current flows or does not flow (or flow to a particular magnitude) in dependence on the threshold voltage when the reading voltage is applied.

In the following, the description of the method concerns the threshold voltage relating to one stored bit, which represents a first or second binary value. If the memory cell comprises two or more threshold voltages which relate to two or more bits, respectively, the method may be performed in order to test the memory cell in respect to each threshold voltage.

In FIG. 1 the memory cells 101 storing the first binary value are indicated by a bold surrounding line. These memory cells 101 are also called “programmed.” Thin surrounding lines indicate the memory cells 100 storing the second binary value. They are also called “erased.”

FIG. 2 shows a typical histogram of the threshold voltages Vt of the memory cells 100, 101, which are comprised by the memory cell array 1. About half of the memory cells 100, 101 are erased and half of them are programmed. The histogram shows the number of memory cells 100, 101 having a certain threshold voltage Vt over the respective threshold voltage Vt. Depending on whether the memory cells 100, 101 are erased or programmed, their threshold Vt is within an erasing range 30 below a reading voltage VR or within a programming range 31 above the reading voltage VR. The histogram comprises two bell-shaped distribution curves 50, 51 within the programming and erasing range 30, 31, respectively. The maximum of the curve 50 of the erased memory cells 100 lies at a mean erasing voltage V1. A mean programming voltage V1 indicates the position of the maximum of the curve 51 of the programmed memory cells 101.

The distribution curve 50 of the erased memory cells 100 has a left tail 200 and a right tail 300. The memory cells within the left tail 200 are called “overerased” and the memory cells within the right tail 300 are called “undererased”.

The overerased memory cells have threshold voltages Vt whose distance from the reading voltage VR is larger than the distance between the threshold voltages Vt of the undererased memory cells and the reading voltage VR.

The distribution curve 51 of the programmed memory cells 101 also has a left tail 400 and a right tail 500. The memory cells within the left tail 400 are called “underprogrammed” and the memory cells within the right tail 500 are called “overprogrammed.” The underprogrammed memory cells 400 have threshold voltages Vt whose distance from the reading voltage VR is less than the distance between the threshold voltages Vt of the overprogrammed memory 500 cells and the reading voltage VR.

Overerased, undererased, underprogrammed and overprogrammed memory cells 200, 300, 400, 500 are indicated in FIGS. 1 to 4 by hatching.

The stored information of erased memory cells 100 is altered by programming. The step of programming comprises applying a programming signal, including a given number of programming pulses to the memory cells 100 to be programmed. In response to the programming pulses, the threshold voltage Vt is shifted from the erasing range 30 to the programming range 31. The amount of the threshold voltage increase, in response to the programming signal, may vary from memory cell 100 to memory cell 100 around the distance between the mean programming voltage V1 and the mean erasing voltage V0. Typically, overerased memory cells 200 are underprogrammed after having been programmed. Likewise, undererased memory cells 300 may become overprogrammed by programming.

Erasing comprises applying an erasing signal, which includes a given number of erasing pulses to the memory cells 101 to be erased. The threshold voltages Vt of the memory cells 101 are reduced in response to the erasing pulses. The amount of the threshold voltage decrease, may vary from memory cell 101 to memory cell 101 around the distance between the mean programming voltage V1 and the mean erasing voltage V0. Typically, overprogrammed and underprogrammed memory cells 500, 400 are undererased and overerased, respectively, after erasing.

The memory cell array 1 may comprise error-free memory cells, defect memory cells and weak memory cells. The latter have a reduced durability compared to the error-free memory cells.

Defective memory cells cannot store information or do not enable to alter the stored information. Detecting defective memory cells is performed during a test routine, e.g., comprising storing information into each memory cell and then trying to alter the stored information. Memory cells which do not store the altered information, are defective. They may be repaired by replacing them by redundant error-free memory cells.

During the life time cycle of the memory cell, its threshold voltage difference decreases. The threshold voltage difference determines the difference between the threshold voltages of the memory cell being programmed and the threshold voltages of the same memory cell being erased. The weak memory cells are overerased or overprogrammed. In addition to that, after performing several programming and erasing cycles the threshold voltage difference of weak memory cells may decrease more significantly than the threshold voltage difference of error-free memory cells. The overerased weak memory cells can be programmed several times until their threshold voltage cannot exceed the reading voltage VR. Weak overprogrammed memory cells can be erased several times until their threshold voltage cannot reach the erasing range 30. The stored information cannot alter. Thus, these memory cells cannot be programmed or erased any longer. They are defective.

Nevertheless not all of the overerased or overprogrammed memory cells 200, 500 are actual weak memory cells. Some of them can be erased and programmed as much as normal error-free memory cells. These memory cells are assumed as error-free.

Assigning the memory cells to overerased or overprogrammed memory cells is based upon the distribution of the threshold voltages Vt of the memory cells 100, 101. The overerased memory cells 200 have threshold voltages Vt which are less than a threshold value TH1. The threshold value TH1 may be a given value or may be defined as a relative deviation from the mean erasing voltage V0. Alternatively, the threshold value may limit the tail as a portion, e.g., 10% of the area under the curve 50. Assigning the memory cells to the overprogrammed memory cells may be based on similar criterions.

In order to distinguish between the actual weak memory cells and the overerased error-free memory cells the threshold voltages Vt of these memory cells 200 are modified by restoring. This step comprises applying at least one further erasing pulse. Due to this, the threshold voltages Vt of the overerased memory cells 200 decrease. The distribution curve 50, in particular the left tail 200 of the distribution curve 50, is widened.

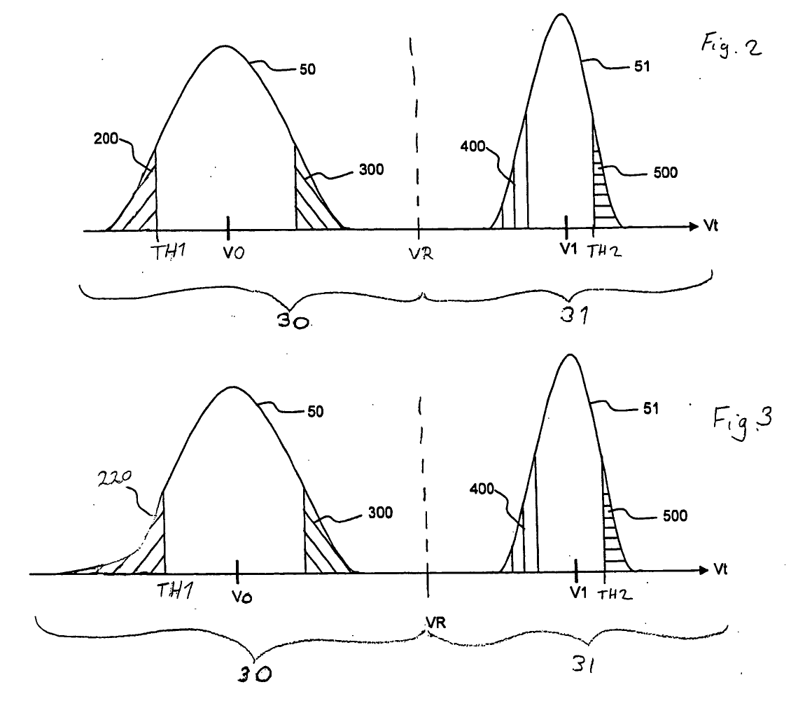

FIG. 3 shows the distribution curves 50, 51 according to FIG. 2, after having restored the overerased memory cells 200 resulting in a widened left tail 220 of the distribution curve 50.

Due to artificial widening of the distribution curve 50, the threshold voltages Vt of the overerased memory cells 220 are shifted away from the reading voltage VR. The amount of shifting varies from memory cell 100 to memory cell 100.

During the following step, the restored overerased memory cells 220 are programmed by applying the programming signal. The threshold voltages Vt of the weak memory cells have been shifted so far away from the reading voltage VR that they cannot exceed the reading voltage VR during the following programming step any more. The weak memory cells have been seasoned by the step of restoring. The error-free overerased memory cells can be programmed, although their threshold voltage Vt has been modified during restoring. The step of restoring enhances the performance of these memory cells. Their threshold voltage as programmed memory cell may be nearer to the mean programming voltage V1 than before. After performing at least one programming and erasing step, their threshold voltage Vt may be closer to the mean erasing voltage V0, too. Thus, restoring may include a tuning effect to overerased or overprogrammed error-free memory cells.

Error-free and weak overerased memory cells can be distinguished by determining whether these memory cells can be programmed or not. The memory cells whose stored information has not altered are assigned to a group of defective memory cells, which may be replaced by redundant memory cells.

Similarly to detecting weak overerased memory cells, weak overprogrammed memory cells can be detected.

Overerased memory cells 500 include error-free and weak memory cells. The threshold voltages Vt of the overprogrammed memory cells 500 are modified by applying at least one further programming pulse resulting in an increased threshold voltage Vt. Thus, the right tail 500 of the distribution curve 51 of programmed memory cells 101 is widened.

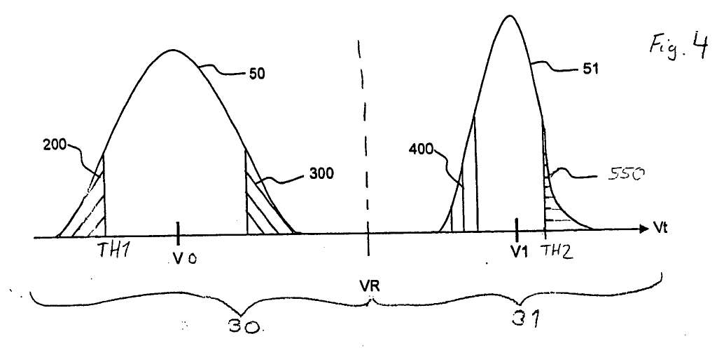

FIG. 4 shows the distribution curves 50, 51 according to FIG. 2, after performing the step of restoring the overprogrammed memory cells 500. Due to this, the right tail 550 of the distribution 51 of programmed memory cells 101 is widened.

During the following step, the restored overprogrammed memory cells 550 are erased by applying the erasing signal. The threshold voltages Vt of the weak memory cells have been increased that they cannot reach the erasing range 30 during the erasing step any more. The error-free overprogrammed memory cells can be erased, although their threshold voltage has been modified by the step of restoring. In this case, restoring also results in an enhanced performance of the error-free memory cells. The threshold voltages Vt of the erased memory cells may be nearer to the mean erasing voltage V0. After performing at least one erasing and programming step, the threshold voltages Vt of these memory cells may be closer to the mean programming voltage V1.

In particular, the method is performed after storing the same information in each memory cell of the memory cell array. This means all memory cells are either programmed or erased before performing the step of assigning weak memory cells.

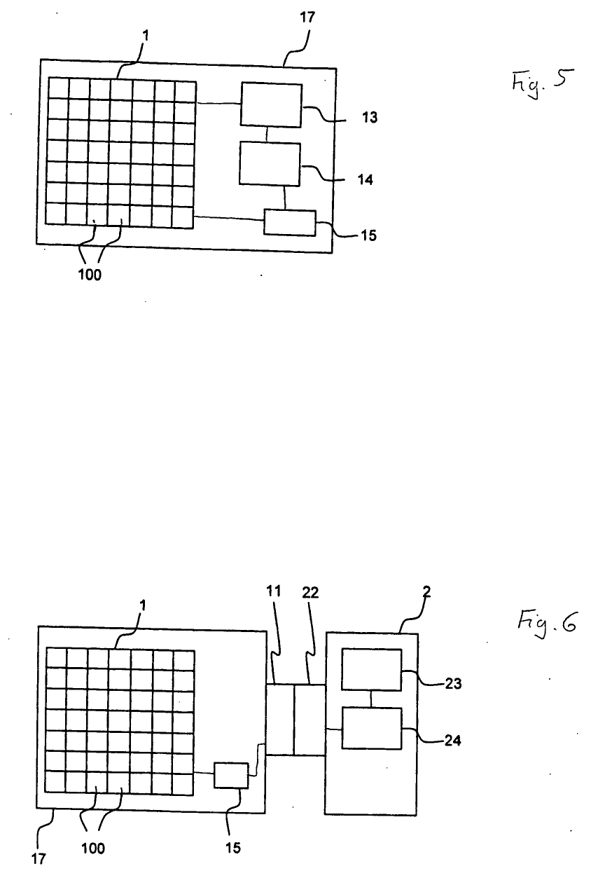

FIG. 5 shows an embodiment of the memory device 17, which enables to perform the above described test method.

The memory device 17, which may be formed on a single semiconductor substrate, comprises a memory cell array 1 including a multitude of memory cells 100 as described above. The memory device 17 further comprises an identifying unit 13 coupled to the memory cell array 1. The identifying unit 13 is operable to identify the threshold voltage Vt of each memory cell 100. The threshold voltage Vt of each memory cell 100 can be determined by applying an increasing reading voltage to the memory cell 100 and monitoring the current flow. When a threshold-like increase of the current flow is detected, the present reading voltage is equal to the threshold voltage Vt.

The memory device 17 further comprises an assigning unit 14 and a memory access unit 15. The assigning unit 14 coupled to the identifying unit 13 is operable to assign memory cells 100 to a weak group containing overerased or overprogrammed memory cells. This assignment of memory cells is based on the identified threshold voltages Vt of the memory cells 100. The assigning unit 14 uses the above-mentioned criterions for assigning.

The access unit 15 coupled to the memory cell array 1 is operable to store information into each memory cell 100. The access unit 15 is further operable to alter the stored information that includes programming or erasing of the respective memory cell 100 supplied with the programming or erasing signal, respectively. The programming or erasing signal is provided by the access unit 15. The programming signal comprises a given number of programming pulses. Likewise, the erasing signal comprises a given number of erasing pulses.

Furthermore, the access unit 15 is operable to restore the stored information into the memory cells assigned to the weak group by means of varying the characteristic without changing the stored information. The access unit 15 is coupled to the assigning unit 14 in order to transmit the information for identifying the memory cells assigned to the weak group from the assigning unit 14 to the access unit 15. Restoring is performed by means which couple a restoring signal to the respective memory cells. In case of overerased memory cells, the restoring signal comprises at least one erasing pulse. In case of overprogrammed memory cells, the restoring signal comprises at least one programming pulse. Due to this, the threshold voltages Vt of the memory cells are shifted away from the reading voltage VR.

FIG. 6 shows a further embodiment of the memory device 17 coupled to a test unit 2 which perform the described test method.

The memory device 17 includes the memory cell array 1 which comprises the multitude of memory cells 100. The memory device 17 further comprises an access unit 15 coupled to the memory cell array 1 which is operable to store information into each memory cell 100 and to alter the stored information. Storing comprises programming or erasing by supplying the memory cell 100 with the programming or erasing signal, respectively. The programming or erasing signal is provided by the access unit 15. The programming signal comprises a given number of programming pulses. Likewise, the erasing signal comprises a given number of erasing pulses.

The access unit 15 is also operable to restore the stored information by means of varying the characteristic of the memory cell. Restoring is performed by means which enables to couple a restoring signal to the respective memory cells. In case of overerased memory cells the restoring signal comprises at least one erasing pulse. In case of overprogrammed memory cells the restoring signal comprises at least one programming pulse.

Identifying the characteristic of each memory cell 100 and assigning memory cells 100 to the weak group, is performed by the external test unit 2.

The memory device 17 comprises an interface 11, which is coupled to an interface 22 of the test unit 2. Information in order to identify the memory cells of the weak group is transmitted from the test unit 2 to the memory device 17. The memory device 17 identifies the memory cells of the weak group and performs the following steps of the test method, including restoring and programming or erasing the memory cells of the weak group.

The test unit 2 comprises an identifying unit 23 and an assigning unit 24. The identifying unit is operable to identify the threshold voltage of each memory cell 100. Identifying the characteristics may be performed by monitoring the current flow while increasing the reading voltage applied to the respective memory cell 100.

The assigning unit 24 assigns memory cells 100 to the weak group. Assigning is performed in the same manner as described above. Furthermore, the test unit or the assigning unit 24 comprises means for generating information in order to identify the memory cells of the weak group. This information is transmitted to the memory device 17 via the connection of the interfaces 11, 22.

The test routine for perfoming the test method may be a functional mode which is available for the manufacturer and can be activated with a secret address combination. In response to the secret address combination the memory device performs the test method, if necessary interacting with the test unit 2.

Normally, this test routine is performed by the manufacturer before delivery in order to repair defective and weak memory cells by replacing them.

Performing the test routine during the life cycle of the memory device is also possible.

What is claimed is:

1. A method of testing a memory cell array that comprises a multitude of memory cells, each memory cell being operable to store information, each memory cell having a variable characteristic that indicates the stored information, the method comprising:
identifying a characteristic of each memory cell;
assigning at least one memory cell of the multitude of memory cells to a weak group based upon the identified characteristic;
restoring the stored information of the memory cells assigned to the weak group in order to modify the characteristic of the memory cells of the weak group.

2. The method in accordance with claim 1, further comprising programming or erasing the memory cells assigned to the weak group in order to alter the stored information of the memory cells assigned to the weak group.

3. The method in accordance with claim 2, further comprising assigning at least one of the memory cells, which are assigned to the weak group, to a defective group, if the stored information of the memory cell has not altered.

4. The method in accordance with claim 1, wherein the characteristic of the memory cell comprises a threshold voltage.

5. The method in accordance with claim 1, wherein the assigning is based upon a distribution curve of the characteristics of the memory cells and wherein the characteristics of the memory cells assigned to the weak group are positioned within a tail of the distribution curve.

6. The method in accordance with claim 5, wherein the distribution curve has a peak positioned at a peak position threshold voltage and restoring is performed in order to increase a distance between the peak position threshold voltage and the characteristics of the memory cells assigned to the weak group.

7. The method in accordance with claim 1, wherein the information is stored by applying a storing signal to the memory cells, the storing signal comprising a sequence of storing pulses.

8. The method in accordance with claim 7, wherein restoring comprises applying a restoring signal to the memory cells assigned to the weak group, the restoring signal comprising at least one storing pulse.

9. A method of testing a memory cell array that comprises a multitude of memory cells, each memory cell being operable to store information, each memory cell having a variable characteristic that indicates the stored information, the method comprising:
identifying a characteristic of each memory cell;
assigning each memory cell to a weak group or an error-free group depending on the identified characteristic;
restoring the stored information of the memory cells assigned to the weak group in order to modify the characteristic of the memory cells of the weak group.

10. The method in accordance with claim 9, further comprising programming or erasing the memory cells assigned to the weak group in order to alter the stored information of the memory cells assigned to the weak group.

11. The method in accordance with claim 10, further comprising assigning each memory cell assigned to the weak group to a defective group, if its stored information has not altered or to the error-free group if its stored information has altered.

12. The method in accordance with claim 9, wherein the characteristic of the memory cell comprises a threshold voltage.

13. The method in accordance with claim 9, wherein the assigning is based upon a distribution curve of the characteristics of the memory cells and wherein the characteristics of the memory cells assigned to the weak group are positioned within a tail of the distribution curve.

14. The method in accordance with claim 13, wherein the distribution curve has a peak positioned at a peak position threshold voltage and restoring is performed in order to increase a distance between the peak position threshold voltage and the characteristics of the memory cells assigned to the weak group.

15. The method in accordance with claim 9, wherein the information is stored by applying a storing signal to the memory cells, the storing signal comprising a sequence of storing pulses.

16. The method in accordance with claim 15, wherein restoring comprises applying a restoring signal to the memory cells assigned to the weak group, the restoring signal comprising at least one storing pulse.

17. A test unit connectable to a memory device comprising a memory cell array, that includes a multitude of memory cells, each memory cell being operable to store information, based upon a characteristic, the test unit comprising:
an identifying unit operable to identify the characteristic of each memory cell;
an assigning unit coupled to the identifying unit, the assigning unit operable to assign at least one memory cell of the multitude of memory cells to a weak group; and
a test unit interface operable to transmit identifying data in order to identify the memory cells assigned to the weak group.

18. The test unit in accordance with claim 17, wherein the assigning unit is operable to determine a distribution of the characteristics of the memory cells and to check each memory cell whether its characteristic lies within a tail of the distribution.

19. The test unit in accordance with claim 17, wherein the assigning unit is operable to check whether the characteristic of each memory cell is within a range limited by a threshold value.

20. A test unit being connectable to a memory device comprising memory cell array that includes a multitude of memory cells, each memory cell operable to store information, based upon a characteristic, the test unit comprising:
an identifying unit operable to identify the characteristic of each memory cell;
an assigning unit coupled to the identifying unit, the assigning unit operable to assign each memory cell to a weak group or an error-free group; and
a test unit interface operable to transmit identifying data in order to identify the memory cells assigned to the weak group.

21. The test unit in accordance with claim 20, wherein the assigning unit is operable to determine a distribution of the characteristics of the memory cells and to check each memory cell whether its characteristic lies within a tail of the distribution.

22. The test unit in accordance with claim 20, wherein the assigning unit is operable to check whether the characteristic of each memory cell is within a range limited by a threshold value.

23. A memory device comprising:
a memory cell array comprising a multitude of memory cells, each memory cell operable to store information, each memory cell having a characteristic;
a memory interface operable to receive identifying data in order to identify memory cells of the multitude of the memory cells that are assigned to a weak group;
an access unit coupled to the memory cell array and to the memory interface, the access unit operable to store the information into each memory cell and to alter the stored information, the access unit operable to restore the stored information by varying the characteristic of the memory cell and further being operable to identify the memory cells assigned to the weak group.

24. The memory device in accordance with claim 23, wherein the access unit is operable to alter the stored information of the memory cells assigned to the weak group.

25. The memory device in accordance with claim 24, further comprising:
a detector to determine whether the stored information of the memory cells assigned to the weak group has altered; and
an assigning unit operable to assign memory cells assigned to the weak group whose stored information has not altered to a defective group.

26. The memory device in accordance with claim 23, wherein the characteristic of the memory cell is a threshold voltage.

27. The memory device in accordance with claim 23, wherein the access unit is operable to provide a storing signal and is further operable to couple the storing signal to the memory cells in order to store the information, the storing signal comprising a sequence of storing pulses.

28. The memory device in accordance with claim 27, wherein the access unit is operable to provide a restoring signal and is further operable to couple the restoring signal to the memory cells assigned to the weak group in order to restore the stored information, the restoring signal comprising at least one storing pulse.

29. A single-chip memory device comprising:
a memory cell array comprising a multitude of memory cells, each memory cell operable to store information, based upon a characteristic;
an identifying unit coupled to the memory cell array, the identifying unit operable to identify the characteristic of each memory cell;
an assigning unit coupled to the identifying unit, the assigning unit operable to assign at least one memory cell of the multitude of memory cells to a weak group; and
an access unit coupled to the assigning unit and to the memory cell array, the access unit operable to store the information into each memory cell, the access unit operable to alter the stored information, and to restore the stored information by varying the characteristic.

30. The memory device in accordance with claim 29, wherein the access unit is operable to alter the stored information of the memory cells assigned to the weak group.

31. The memory device in accordance with claim 30, further comprising:
a detector operable to detect whether the stored information of the memory cells assigned to the weak group has been altered; and
a unit operable to assign assigning memory cells assigned to the weak group whose stored information has not altered to a defect group.

32. The memory device in accordance with claim 29, wherein the characteristic of the memory cell comprises a threshold voltage.

33. The memory device in accordance with claim 27, wherein the assigning unit is operable to determine a distribution of the characteristics of the memory cells and to check each memory cell whether its characteristic lies within a tail of the distribution.

34. The memory device in accordance with claim 27, wherein the assigning unit is operable to check whether the characteristic of each memory cell is within a range limited by a threshold value.

35. The memory cell array in accordance with claim 34, wherein the access unit is operable during restoring to increase a distance between the characteristics of the memory cells assigned to the weak group and the threshold value.

36. The memory cell array in accordance with claim 27, wherein the access unit is operable to provide a storing signal and is further operable to couple the storing signal to the memory cells in order to store the information, the storing signal comprising a sequence of storing pulses.

37. The memory cell array in accordance with claim 36, wherein the access unit is operable to provide a restoring signal and is further operable to couple the restoring signal to the memory cells assigned to the weak group in order to restore the stored information, the restoring signal comprises at least one storing pulse.

38. A single-chip memory device comprising:
a memory cell array comprising a multitude of memory cells, each memory cell operable to store information based upon a characteristic;
an identifying unit coupled to the memory cell array, the identifying unit operable to identify the characteristic of each memory cell;
an assigning unit coupled to the identifying unit, the assigning unit operable to assign each memory cell to a weak group or to an error-free group; and
an access unit coupled to the assigning unit and to the memory cell array, the access unit operable to store the information into each memory cell, the access unit operable to alter the stored information and operable to restore the stored information by varying the characteristic.

39. The memory device in accordance with claim 38, wherein the access unit is operable to alter the stored information of the memory cells assigned to the weak group.

40. The memory device in accordance with claim 39, further comprising:
a detector operable to detect whether the stored information of the memory cells assigned to the weak group has been altered; and
a unit operable to assign assigning the memory cells which are assigned to the weak group to a defect group if the stored information has not altered or to the error-free group if the stored information has altered.

41. The memory device in accordance with claim 38, wherein the characteristic of the memory cell comprises a threshold voltage.

42. The memory device in accordance with claim 38, wherein the assigning unit is operable to determine a distribution of the characteristics of the memory cells and to check each memory cell whether its characteristic lies within a tail of the distribution.

43. The memory device in accordance with claim 38, wherein the assigning unit is operable to check whether the characteristic of each memory cell is within a range limited by a threshold value.

44. The memory cell array in accordance with claim 43, wherein the access unit is operable during restoring to increase a distance between the characteristics of the memory cells assigned to the weak group and the threshold value.

45. The memory cell array in accordance with claim 38, wherein the access unit is operable to provide a storing signal and is further operable to couple the storing signal to the memory cells in order to store the information, the storing signal comprising a sequence of storing pulses.

46. The memory cell array in accordance with claim 38, wherein the access unit is operable to provide a restoring signal and is further operable to couple the restoring signal to the memory cells assigned to the weak group in order to restore the stored information, the restoring signal comprises at least one storing pulse.
